(19) United States
(12) Patent Application Publication
(10) Pub. No.: US 2025/0234761 A1
(43) Pub. Date: Jul. 17, 2025

(54) DISPLAY MODULE, METHOD OF MANUFACTURING A DISPLAY MODULE, AND DISPLAY APPARATUS

(71) Applicant: WUHAN CHINA STAR OPTOELECTRONICS SEMICONDUCTOR DISPLAY TECHNOLOGY CO., LTD., Wuhan (CN)

(72) Inventors: Mengwei ZHU, Wuhan (CN); Wen HAN, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 18/622,875

(22) Filed: Mar. 30, 2024

Related U.S. Application Data
(63) Continuation of application No. PCT/CN2024/073607, filed on Jan. 23, 2024.

(30) Foreign Application Priority Data
Jan. 11, 2024 (CN) 202410047928.9

(51) Int. Cl. H10K 59/80; H10K 71/00; H10K 102/00

(52) U.S. Cl. CPC H10K 59/8792; H10K 59/8793; H10K 71/00; H10K 2102/311; H10K 2102/351

(57) ABSTRACT

A display module includes a display panel, a stress buffer layer, a protective layer and a first light-shielding layer. The display panel includes a planar area and a curved surface area. The stress buffer layer is disposed on a light exit side of the display panel and opposite to the planar area and part of the curved surface area. The protective layer is disposed on a surface of the stress buffer layer away from the display panel, and includes a planar portion opposite to the planar area and a curved portion opposite to the curved surface area. The first light-shielding layer is disposed in the stress buffer layer or between the stress buffer layer and the display panel, and is opposite to part of the curved portion. An edge of the first light-shielding layer is aligned with an edge of the stress buffer layer.

### CROSS-REFERENCE TO RELATED APPLICATIONS

This application is a continuation of International Application No. PCT/CN2024/073607, filed on Jan. 23, 2024, which claims priority to Chinese Patent Application No. 202410047928.9, filed on Jan. 11, 2024. The disclosures of the abovementioned applications are incorporated herein by reference in their entireties.

### TECHNICAL FIELD

The present application relates to display technologies, and in particular to a display module, a method of manufacturing a display module, and a display apparatus.

### BACKGROUND

With the development of flexible display technologies and the growing demands of users, users' requirements for visual experience are gradually upgrading, and terminal devices such as mobile phones and tablet computers are also gradually developing to have larger screen-to-body ratios. More and more display apparatuses begin to use curved display modules.

A display module with four curved surfaces has four rounded corner areas each of which is a Gaussian three-dimensional curved surface area. A portion of the display module bonded in the Gaussian three-dimensional curved surface area is subject to forces in three directions, and thus is prone to phenomena such as wrinkles or bubbles. In addition, in a non-display area within the curved surface area, generally a light-shielding layer is coated on an inner surface of a cover plate to shield the non-display area of the display module, thereby avoiding light leakage from the non-display area. During the process of bonding the curved surfaces, a display portion of a display panel is bonded to the inner surface of the cover plate, and a non-display portion of the display panel is entirely bonded to an inner surface of the light-shielding layer. Since a step difference exists between the inner surface of the light-shielding layer and the inner surface of the cover plate, uneven stress on the display panel in each rounded corner area is deteriorated, leading to an increased risk of wrinkles or bubbles in the rounded corner area.

### SUMMARY

A display module according to one or more embodiments of the present application includes: a display panel, a stress buffer layer, a protective layer and a first light-shielding layer. The display panel includes a planar area and a curved surface area disposed at an edge of the planar area; the stress buffer layer is disposed on a light exit side of the display panel to be opposite to the planar area and a part of the curved surface area; the protective layer is disposed on a surface of the stress buffer layer away from the display panel, the protective layer includes a planar portion and a curved portion, the planar portion is disposed opposite to the planar area, and the curved portion is disposed opposite to the curved surface area; the first light-shielding layer is disposed in the stress buffer layer or between the stress buffer layer and the display panel to be opposite to a part of the curved portion, and an edge of the first light-shielding layer is aligned with an edge of the stress buffer layer.

A method of manufacturing a display module according to one or more embodiments of the present application is used to manufacture the display module provided in any one of the embodiments. The method includes: forming a first light-shielding layer in a stress buffer layer or on a surface of the stress buffer layer, an edge of the first light-shielding layer being aligned with an edge of the stress buffer layer; providing a protective layer including a planar portion and a curved portion disposed at an edge of the planar portion; bonding a surface of a part of the stress buffer layer that is not provided with the first light-shielding layer to a surface of the planar portion and a surface of a part of the curved portion; and bonding a display panel to a surface of the stress buffer layer away from the protective layer to form the display module, the display panel including a planar area and a curved surface area disposed at an edge of the planar area, the planar area being disposed opposite to the planar portion, and the curved surface area being disposed opposite to the curved portion.

A display apparatus according to one or more embodiments of the present application includes a display module, and the display module includes: a display panel, a stress buffer layer, a protective layer and a first light-shielding layer. The display panel includes a planar area and a curved surface area disposed at an edge of the planar area; the stress buffer layer is disposed on a light exit side of the display panel to be opposite to the planar area and a part of the curved surface area; the protective layer is disposed on a surface of the stress buffer layer away from the display panel, the protective layer includes a planar portion and a curved portion, the planar portion is disposed opposite to the planar area, and the curved portion is disposed opposite to the curved surface area; the first light-shielding layer is disposed in the stress buffer layer or between the stress buffer layer and the display panel to be opposite to a part of the curved portion, and an edge of the first light-shielding layer is aligned with an edge of the stress buffer layer.

### BRIEF DESCRIPTION OF THE DRAWINGS

FIG. 1 is a schematic plan view of a display module according to one or more embodiments of the present application.

FIG. 2 is a cross-sectional view of a first example of a display module along the A-A′ direction shown in FIG. 1 according to one or more embodiments of the present application.

FIG. 3 is a cross-sectional view of a second example of a display module along the A-A′ direction shown in FIG. 1 according to one or more embodiments of the present application.

FIG. 4 is a cross-sectional view of a third example of a display module along the A-A′ direction shown in FIG. 1 according to one or more embodiments of the present application.

FIG. 5 is a cross-sectional view of a fourth example of a display module along the A-A′ direction shown in FIG. 1 according to one or more embodiments of the present application.

FIG. 6 is a cross-sectional view of a fifth example of a display module along the A-A′ direction shown in FIG. 1 according to one or more embodiments of the present application.

FIGS. 7A and 7B schematically illustrate a process of manufacturing a display module according to one or more embodiments of the present application.

FIG. 8 is a block diagram of a display apparatus according to one or more embodiments of the present application.

### DETAILED DESCRIPTION

The following description of embodiments refers to the accompanying drawings to illustrate specific embodiments that may be implemented in the present application. Directional terms mentioned in the present application, such as “upper”, “lower”, “front”, “back”, “left”, “right”, “inner”, “outer” and “side” are for referring to the accompanying drawings only. Therefore, the directional terms used are to illustrate and describe the present application, but not to limit the present application. In the accompanying drawings, units with similar structures are represented by the same numbers.

Embodiments of the present application provide a display module, a method of manufacturing the display module and a display apparatus, each of which may ameliorate the uneven stress on the display panel during the process of bonding a curved surface and reduce the risk of wrinkles or bubbles happening to the display module.

The display module according to one or more embodiments of the present application includes: a display panel, a stress buffer layer, a protective layer and a first light-shielding layer. The display panel includes a planar area and a curved surface area disposed at an edge of the planar area; the stress buffer layer is disposed on a light exit side of the display panel to be opposite to the planar area and a part of the curved surface area; the protective layer is disposed on a surface of the stress buffer layer away from the display panel, the protective layer includes a planar portion and a curved portion, the planar portion is disposed opposite to the planar area, and the curved portion is disposed opposite to the curved surface area; the first light-shielding layer is disposed in the stress buffer layer or between the stress buffer layer and the display panel to be opposite to a part of the curved portion, and an edge of the first light-shielding layer is aligned with an edge of the stress buffer layer.

According to an embodiment of the present application, the curved portion includes a first curved portion, and a second curved portion connected to the first curved portion and disposed on a side of the first curved portion away from the planar portion; the first light-shielding layer is disposed opposite to at least a part of the first curved portion; and the display module further includes a second light-shielding layer at least partially disposed on a surface of the second curved portion close to the display panel.

According to an embodiment of the present application, an edge of the first light-shielding layer close to the second curved portion is aligned with an edge of the second light-shielding layer close to the first curved portion.

According to an embodiment of the present application, an end of the first light-shielding layer close to the second curved portion overlaps an end of the second light-shielding layer close to the first curved portion.

According to an embodiment of the present application, the second light-shielding layer is partially disposed on a side surface of the second curved portion away from the first curved portion.

According to an embodiment of the present application, the second light-shielding layer has a thickness equal to that of the first light-shielding layer, and includes a same material as the first light-shielding layer.

According to an embodiment of the present application, the first curved portion has a greater radius of curvature than the second curved portion.

According to an embodiment of the present application, the first light-shielding layer has a thickness greater than or equal to 15 microns and less than or equal to 20 microns.

According to an embodiment of the present application, an end of the display panel close to the second curved portion protrudes from each of an end of the stress buffer layer close to the second curved portion and an end of the first light-shielding layer close to the second curved portion.

According to an embodiment of the present application, the display module further includes a third light-shielding layer disposed on a side surface of the stress buffer layer close to the second curved portion.

According to an embodiment of the present application, the stress buffer layer includes a first transparent adhesive layer and a base material layer. The first transparent adhesive layer is disposed on an inner surface of the planar portion and an inner surface of a part of the curved portion; the base material layer is disposed between the first transparent adhesive layer and the display panel. The first light-shielding layer is disposed between the base material layer and the display panel or between the first transparent adhesive layer and the base material layer.

According to an embodiment of the present application, the base material layer has an elastic modulus greater than or equal to 2 GPa and less than or equal to 6 GPa.

According to an embodiment of the present application, the base material layer includes polyethylene terephthalate or polyimide.

According to an embodiment of the present application, the base material layer has a thickness greater than or equal to 50 microns and less than or equal to 100 microns.

According to an embodiment of the present application, the first transparent adhesive layer has a thickness greater than or equal to 50 microns and less than or equal to 200 microns.

According to an embodiment of the present application, the display module further includes a polarizing layer and a second transparent adhesive layer; the polarizing layer is disposed between the display panel and the stress buffer layer; the second transparent adhesive layer is disposed between the polarizing layer and the stress buffer layer; and the first light-shielding layer is disposed between the second transparent adhesive layer and the stress buffer layer.

According to an embodiment of the present application, the display module further includes a support layer disposed on a surface of the display panel away from the protective layer.

The method of manufacturing a display module according to one or more embodiments of the present application is used to manufacture the display module provided in any one of the embodiments. The method includes: forming a first light-shielding layer in a stress buffer layer or on a surface of the stress buffer layer, an edge of the first light-shielding layer being aligned with an edge of the stress buffer layer; providing a protective layer including a planar portion and a curved portion disposed at an edge of the planar portion; bonding a surface of a part of the stress buffer layer that is not provided with the first light-shielding layer to a surface of the planar portion and a surface of a part of the curved portion; and bonding a display panel to a surface of the stress buffer layer away from the protective layer to form the display module, the display panel including a planar area and a curved surface area disposed at an edge of the planar area, the planar area being disposed opposite to the planar portion, and the curved surface area being disposed opposite to the curved portion.

According to an embodiment of the present application, the curved portion includes a first curved portion, and a second curved portion connected to the first curved portion and disposed on a side of the first curved portion away from the planar portion. The method further includes: before forming the first light-shielding layer, forming a second light-shielding layer on a first surface of the second curved portion at a concave side of the second curved portion or on both the first surface and a side surface of the second curved portion away from the first curved portion.

A display apparatus according to one or more embodiments of the present application includes the display module provided in any one of the above embodiments.

The embodiments of the present application have following beneficial effects. The display module includes the protective layer, the stress buffer layer, the display panel and the first light-shielding layer. Since the stress buffer layer is added between the protective layer and the display panel, the stress buffer layer may absorb the stress generated during the process of bonding the curved surface, thereby ameliorating the uneven stress on the display panel during the process of bonding the curved surface. Based on this, by arranging the first light-shielding layer in the stress buffer layer or between the stress buffer layer and the display panel, the stress buffer layer may be fully bonded to the inner surface of the protective layer, which avoids the step difference existing between the part of the stress buffer layer corresponding to the planar portion and the part of the stress buffer layer corresponding to the curved portion. Therefore, it may further ameliorate the uneven stress on the display panel during the process of bonding the curved surface, thereby further reducing the risk of wrinkles or bubbles happening to the display panel.

Some embodiments of the present application will be described in detail below in conjunction with the accompanying drawings.

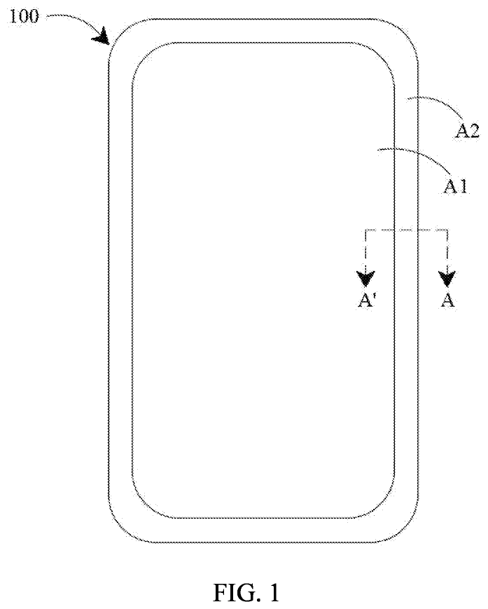

FIG. 1 is a schematic plan view of the display module according to one or more embodiments of the present application. The display module 100 includes a display panel, and the display panel includes a planar area A1 and a curved surface area A2 disposed at an edge of the planar area A1. The curved surface area A2 is arranged around the planar area A1. A portion of the display panel in the planar area A1 is in a flat state, and an outer surface of the portion is a flat surface. A portion of the display panel in the curved surface area A2 is in a curved state, and an outer surface of the portion is a curved surface. The portion of the display panel in the curved surface area A2 is curved toward a direction opposite to a light exit direction of the display panel.

In embodiments of the present application, a front surface of the display panel is in a shape of a rounded rectangle in the top view shown in FIG. 1. The display panel has a structure of four curved surfaces. The planar area A1 is fully surrounded by the curved surface area A2, and in the planar area A1, sub-areas at upper side, lower side, left side and right side, and sub-areas at four rounded corners each have a curved structure therein, and each of the rounded corners is connected to two of the four sides adjacent to the rounded corner.

In some other embodiments, the shape of the front surface of the display panel in the top view shown in FIG. 1 is not limited to the rounded rectangle in the above embodiments, and may also be a circle, an ellipse, or other polygon. The curved surface area A2 may also surround part of the planar area A1. For example, the curved surface area A2 is only provided at the left side, right side and upper side of the planar area A1, and at rounded corners each connected to any two adjacent sides, and the lower side of the planar area A1 is provided with no curved surface area A2.

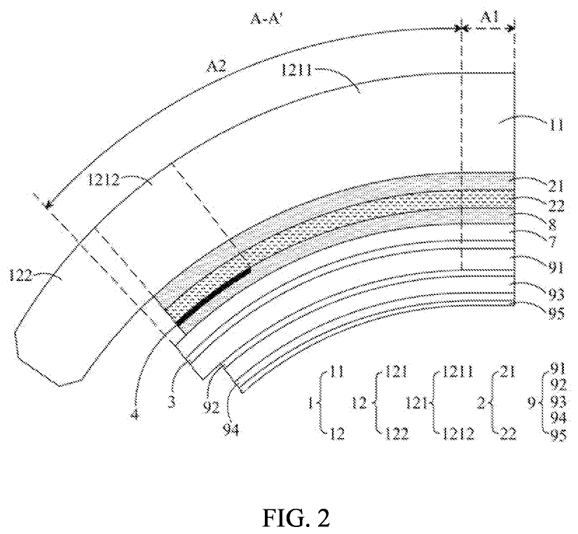

FIG. 2 is a cross-sectional view of a first example of a display module along the A-A′ direction shown in FIG. 1 according to one or more embodiments of the present application. The display module 100 includes a protective layer 1, a stress buffer layer 2 and the display panel 3.

The display panel 3 is a flexible display panel. The display panel may be, but is not limited to, an organic light-emitting diode (OLED) display panel or a micro light-emitting diode (Micro LED) display panel. For film structures of the display panel 3, reference may be made to structures of an existing flexible display panel, which is no limited herein.

The stress buffer layer 2 is disposed on a light exit side of the display panel 3 to be opposite to the planar area A1 and a part of the curved surface area A2. The protective layer 1 is disposed on a surface of the stress buffer layer 2 away from the display panel 3.

The protective layer 1 includes a planar portion 11 and a curved portion 12. The curved portion 12 is disposed at an edge of the planar portion 11. The planar portion 11 is disposed opposite to the planar area A1 of the display panel 3, and the curved portion 12 is disposed opposite to the curved surface area A2 of the display panel 3. The curved direction of the curved portion 12 is consistent with the curved direction of the curved surface area A2 of the display panel 3. That is, the shape of the display panel 3 matches the shape of the protective layer 1. An outer surface of the protective layer 1 may serve as an outer surface of the display module 100. An inner surface of the protective layer 1 is opposite to the outer surface thereof, and the inner surface of the protective layer 1 is closer to the display panel than the outer surface thereof.

In embodiments of the present application, the curved portion 12 is disposed around the planar portion 11, and the planar portion 11 is fully surrounded by the curved portion 12. A curvature of the curved portion 12 may refer to a curvature of a protective layer in the existing curved display module, which is not limited herein.

In an embodiment, the protective layer 1 is made of glass. That is, the protective layer 1 is a glass cover. In some other embodiments, the material of the protective layer 1 is not limited to glass, but may also be other hard transparent protective material(s).

The stress buffer layer 2 is disposed on the light exit side of the display panel 3. A part of the stress buffer layer 2 is disposed on a surface of the display panel 3 in the planar area A1, and another portion of the stress buffer layer 2 is disposed on a surface of the display panel 3 in a part of the curved surface area A2. The shape of the stress buffer layer 2 matches the shape of the protective layer 1. A part of the stress buffer layer 2 overlapping the planar area A1 has a flat surface, and a part of the stress buffer layer 2 overlapping the curved surface area A2 is curved toward the direction opposite to the light exit direction of the display panel 3. Since the stress buffer layer 2 is added between the protective layer 1 and the display panel 3, the stress buffer layer 2 may absorb the stress generated during the process of bonding the curved surface, thereby ameliorating the uneven stress on the display panel 3 during the process of bonding the curved surface. As a result, the risk of wrinkles or bubbles during the process of bonding the curved surface may be reduced to a certain extent.

In some embodiments, the stress buffer layer 2 includes a first transparent adhesive layer 21 and a base material layer 22. The first transparent adhesive layer 21 is disposed on an inner surface of the planar portion 11 and an inner surface of a part of the curved portion 12, and the base material layer 22 is disposed between the first transparent adhesive layer 21 and the display panel 3. A material of the first transparent adhesive layer 21 may be, but is not limited to, an optical adhesive. The first transparent adhesive layer 21 is used to enable the base material layer 22 to be bonded on a surface of the protective layer 1 close to the display panel 3. A first light-shielding layer 4 is provided between the base material layer 22 and the display panel 3.

Further, an elastic modulus of the base material layer 22 is greater than or equal to 2 GPa and less than or equal to 6 GPa.

In an embodiment, the elastic modulus of the base material layer 22 is 2 GPa. In some other embodiments, the elastic modulus of the base material layer 22 may also be 3 GPa, 4 GPa, 5 GPa or 6 GPa, etc.

Further, the base material layer 22 is made of polyethylene terephthalate or polyimide.

In an embodiment, the material of the base material layer 22 is polyethylene terephthalate.

In another embodiment, the material of the base material layer 22 is polyimide, and the polyimide may be yellow polyimide or transparent polyimide.

Further, a thickness of the base material layer 22 is greater than or equal to 50 microns and less than or equal to 100 microns.

In an embodiment, the thickness of the base material layer 22 is 50 microns. In some other embodiments, the thickness of the base material layer 22 may also be 60 microns, 80 microns, 90 microns or 100 microns, etc., and the thickness of the base material layer 22 only needs to be between 50 microns and 100 microns.

Further, a thickness of the first transparent adhesive layer 21 is greater than or equal to 50 microns and less than or equal to 200 microns.

In an embodiment, the thickness of the first transparent adhesive layer 21 is 50 microns. In other embodiments, the thickness of the first transparent adhesive layer 21 may also be 80 microns, 120 microns, 150 microns, 180 microns or 200 microns, etc.

The display module 100 further includes the first light-shielding layer 4. The first light-shielding layer 4 is disposed in the stress buffer layer 2 or between the stress buffer layer 2 and the display panel 3 to be opposite to a part of the curved portion 12, and an edge of the first light-shielding layer 4 is aligned with an edge of the stress buffer layer 2.

Specifically, the curved portion 12 includes a first curved portion 121 and a second curved portion 122. The first light-shielding layer 4 is disposed opposite to at least a part of the first curved portion 121. The second curved portion 122 is connected to the first curved portion 121, and the second curved portion 122 is disposed on a side of the first curved portion 121 away from the planar portion 11. An end of the first curved portion 121 away from the second curved portion 122 is connected to the planar portion 11. The planar portion 11, the first curved portion 121 and the second curved portion 122 are of an integral structure. A curvature of the second curved portion 122 is greater than a curvature of the first curved portion 121.

The first curved portion 121 includes a first curved sub-portion 1211 and a second curved sub-portion 1212. The second curved sub-portion 1212 is located between the first curved sub-portion 1211 and the second curved portion 122, and the first curved sub-portion 1211 is connected to the planar portion 11 and the second curved sub-portion 1212.

In an embodiment, as shown in FIG. 2, the first light-shielding layer 4 is disposed between the base material layer 22 and the display panel 3, and the first light-shielding layer 4 is disposed opposite to the second curved sub-portion 1212. Thus, an area corresponding to the second curved sub-portion 1212 is opaque, and an area corresponding to the first curved sub-portion 1211 is light-transmissive. That is, portions of the display module 100 corresponding to the first curved sub-portion 1211 and the planar portion 11 together have the function of displaying images, and portions of the display module 100 corresponding to the second curved sub-portion 1212 and the second curved portion 122 do not have the function of performing the image display.

In the embodiments of the present application, since the first light-shielding layer 4 is disposed between the stress buffer layer 2 and the display panel 3, the stress buffer layer 2 may be fully bonded to the inner surface of the protective layer 1 while ensuring that light leakage does not happen to the curved surface area A2 of the display module. Thus, it may be possible to avoid a step difference existing between different portions of the stress buffer layer 2. Therefore, it may further ameliorate the uneven stress on the display panel during the process of bonding the curved surface, thereby further reducing the risk of wrinkles or bubbles happening to the display panel.

In an embodiment, the first light-shielding layer 4 is disposed opposite to the first curved portion 121. That is, the first light-shielding layer 4 covers the inner surface of the first curved portion 121. With this arrangement, the portion of the display module 100 corresponding to the planar portion 11 has the function of displaying images, and the portion of the display module 100 corresponding to the curved portion 12 does not have the function of performing the image display.

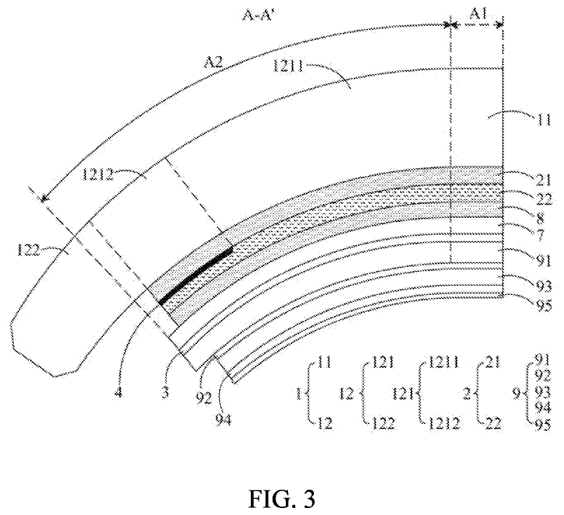

FIG. 3 is a cross-sectional view of a second example of a display module along the A-A′ direction shown in FIG. 1 according to one or more embodiments of the present application. The structure shown in FIG. 3 is substantially the same as the structure of the display module shown in FIG. 2, with the difference being that the first light-shielding layer 4 is disposed in the stress buffer layer 2.

As shown in FIG. 3, the first light-shielding layer 4 is disposed between the base material layer 22 and the first transparent adhesive layer 21. With this arrangement, the first transparent adhesive layer 21 may be fully bonded to the inner surface of the protective layer 1. Thus, it may also be possible to avoid the step difference existing between different portions of the stress buffer layer 2. Therefore, it may further ameliorate the uneven stress on the display panel during the process of bonding the curved surface, thereby further reducing the risk of wrinkles or bubbles happening to the display panel.

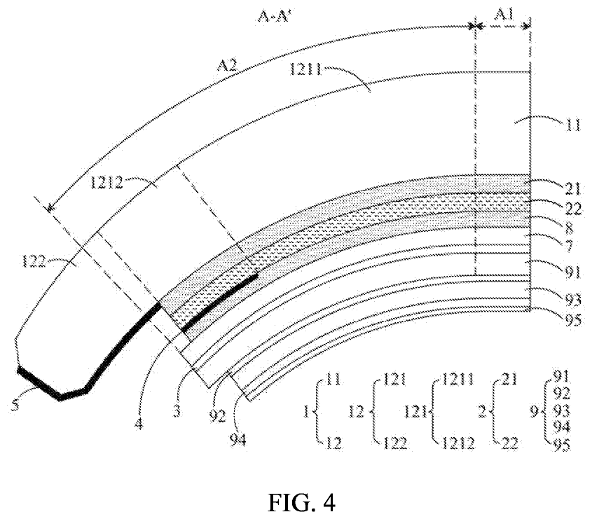

FIG. 4 is a cross-sectional view of a third example of a display module along the A-A′ direction shown in FIG. 1 according to one or more embodiments of the present application. The structure shown in FIG. 4 is substantially the same as the structure of the display module shown in FIG. 2, with the difference being that the display module 100 further includes a second light-shielding layer 5, and the second light-shielding layer 5 is at least partially disposed on an inner surface of the second curved portion 122.

As shown in FIG. 4, the second light-shielding layer 5 is at least partially disposed on a surface of the second curved portion 122 close to the display panel 3, and the second light-shielding layer 5 is used to shield the second curved portion 122 to prevent the light emitted by the display panel 3 from exiting from the second curved portion 122. The second light-shielding layer 5 is added on the inner surface of the second curved portion 122 to shield the second curved portion 122 in the embodiments of the present application, which further increases an area of the curved portion 12 being shield.

In the embodiments, as shown in FIG. 4, the second light-shielding layer 5 and the first light-shielding layer 4 are designed in segments, the second light-shielding layer 5 is directly disposed on the surface of the second curved portion 122 of the protective layer 1 close to the display panel 3, and the first light-shielding layer 4 is disposed between the stress buffer layer 2 and the display panel 3. In this way, the stress buffer layer 2 may be fully bonded to the inner surface of the protective layer 1 while ensuring that light leakage does not happen to the curved surface area A2 of the display module. Thus, it avoids a step difference existing between a part of the stress buffer layer corresponding to the planar portion and a part of the stress buffer layer corresponding to the curved portion. Therefore, it may further ameliorate the uneven stress on the display panel during the process of bonding the curved surface, thereby further reducing the risk of wrinkles or bubbles happening to the display panel.

In an embodiment, the second light-shielding layer 5 is partially disposed on a side surface of the second curved portion 122 away from the first curved portion 121.

As shown in FIG. 4, the second light-shielding layer 5 is continuously arranged on the inner surface of the second curved portion 122 close to the display panel 3 and on the side surface of the second curved portion 122 away from the first curved portion 121, which may avoid the problem of light leakage happening to the side of the protective layer 1 at a large viewing angle.

In some embodiments, an edge of the first light-shielding layer 4 close to the second curved portion 122 is aligned with an edge of the second light-shielding layer 5 close to the first curved portion 121.

As shown in FIG. 4, the stress buffer layer 2 and the second light-shielding layer 5 are both disposed on the inner surface of the protective layer 1, and there is no other film layer between the stress buffer layer 2 and the protective layer 1. A side surface of the stress buffer layer 2 close to the second curved portion 122 is aligned with and attached to a side surface of the second light-shielding layer 5 close to the first curved portion 121, and the edge of the first light-shielding layer 4 close to the second curved portion 122 is aligned with the edge of the second light-shielding layer 5 close to the first curved portion 121. Since the thickness of the first transparent adhesive layer 21 is greater than the thickness of the second light-shielding layer 5, and the side surface of the first transparent adhesive layer 21 is aligned with and attached to the side surface of the second light-shielding layer 5, the side surface of the base material layer 22 and the side surface of the second light-shielding layer 5 are misalignment. With this arrangement, there is no gap between the stress buffer layer 2 and the second light-shielding layer 5. Orthographic projections of the first light-shielding layer 4 and the second light-shielding layer 5 on the protective layer 1 may be seamlessly connected, which avoids the light from exiting from a gap between the first light-shielding layer 4 and the second light-shielding layer 5.

Further, the edge of the first light-shielding layer 4 close to the second curved portion 122 is aligned with the edge of the stress buffer layer 2 close to the second curved portion 122.

As shown in FIG. 4, since the edge of the first light-shielding layer 4 close to the second curved portion 122 is aligned with the edge of the stress buffer layer 2 close to the second curved portion 122, the side surface of the first light-shielding layer 4 close to the second curved portion 122 and side surfaces, close to the second curved portion 122, of the first transparent adhesive layer 21 and the base material layer 22 of the stress buffer layer 2 are located on a same inclined plane, and in an extension direction of the inclined plane, the side surface of the first light-shielding layer 4 close to the second curved portion 122 is aligned with the side surface of the second light-shielding layer 5 close to the first curved portion 121. Thus, it may be possible to ensure that projections of the second light-shielding layer 5 and the first light-shielding layer 4 on the inner surface of the protective layer 1 cover the inner surface of the protective layer 1, thereby avoiding the light from exiting from a gap between the second light-shielding layer 5 and the first light-shielding layer 4.

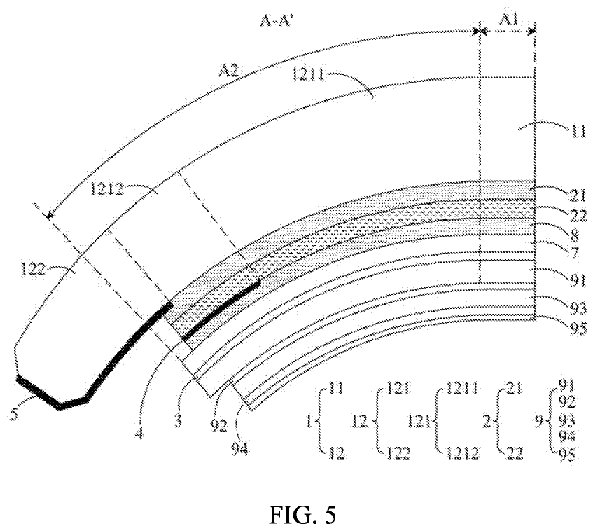

FIG. 5 is a cross-sectional view of a fourth example of a display module along the A-A′ direction shown in FIG. 1 according to one or more embodiments of the present application. The structure shown in FIG. 5 is substantially the same as the structure of the third display module shown in FIG. 4, with the difference being that the end of the first light-shielding layer 4 close to the second curved portion 122 overlaps the end of the second light-shielding layer 5 close to the first curved portion 121.

It will be noted that, in the actual assembly process, a certain error exists in the bonding between the stress buffer layer 2 and the protective layer 1. In the embodiments, as shown in FIG. 5, in order to ensure that there is no light-leakage gap between the stress buffer layer 2 and the second light-shielding layer 5, the end of the stress buffer layer 2 close to the second curved portion 122 is bonded to the surface of the second light-shielding layer 5 away from the second curved portion 122, so that the end of the first light-shielding layer 4 close to the second curved portion 122 overlaps the end of the second light-shielding layer 5 close to the first curved portion 121, thereby avoiding a gap existing between the first light-shielding layer 4 and the second light-shielding layer 5 to leak light. Compared with the prior art where a light-shielding layer with a relatively large area exists between the display panel and the protective layer, in the embodiments, as shown in FIG. 5, only a small overlapping area exists between the first light-shielding layer 4 and the second light-shielding layer 5 at the boundary between the first curved portion 121 and the second curved portion 122, which may avoid the light-leakage gap existing between the first light-shielding layer 4 and the second light-shielding layer 5 while ensuring that the uneven stress on the display panel will not be intensified during the process of bonding the curved surface.

In some embodiments, a thickness of the second light-shielding layer 5 is the same as a thickness of the first light-shielding layer 4, and a material of second light-shielding layer 5 is the same as a material of the first light-shielding layer 4. Thus, it may be possible to ensure that the light transmittance of the second light-shielding layer 5 is consistent with the light transmittance of the first light-shielding layer 4, thereby avoiding poor visual effects of the display module caused by a difference existing between transmittances of the second light-shielding layer 5 and the first light-shielding layer 4.

Further, the thickness of the first light-shielding layer 4 is greater than or equal to 15 microns and less than or equal to 20 microns.

In an embodiment, the thicknesses of the second light-shielding layer 5 and the first light-shielding layer 4 are both 15 microns.

In some other embodiments, the thickness of the first light-shielding layer 4 is not limited to 15 microns, but may also be 16 microns, 17 microns, 18 microns, 19 microns or 20 microns, etc. The thickness of the first light-shielding layer 4 only needs to be between 15 microns and 20 microns, and thus the step difference between the stress buffer layer 2 and the display panel 3 being too large caused by an excessive thickness of the first light-shielding layer 4 may be avoided, and thereby the uneven stress may be avoided. The thicknesses of the second light-shielding layer 5 and the first light-shielding layer 4 are the same.

In an embodiment, both the second light-shielding layer 5 and the first light-shielding layer 4 are made of black ink. In practical applications, the materials of the second light-shielding layer 5 and the first light-shielding layer 4 are not limited to the black ink, but may also be other black opaque material(s), which are not uniquely limited herein.

In some embodiments, as shown in FIG. 4, an end of the display panel 3 close to the second curved portion 122 protrudes from each of the end of the stress buffer layer 2 close to the second curved portion 122 and the end of the first light-shielding layer 4 close to the second curved portion 122.

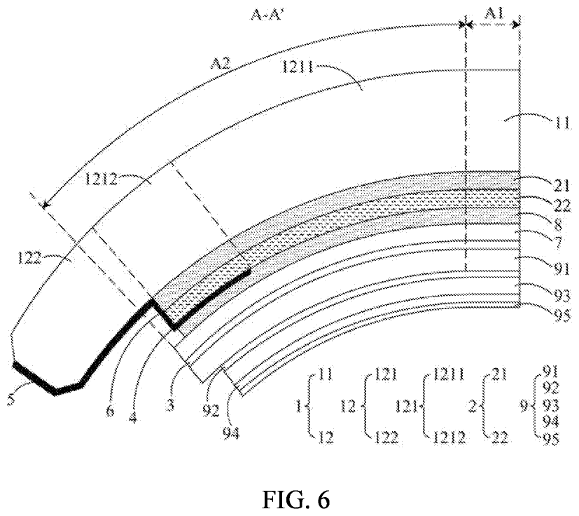

FIG. 6 is a cross-sectional view of a fifth example of a display module along the A-A′ direction shown in FIG. 1 according to one or more embodiments of the present application. The structure shown in FIG. 6 is substantially the same as the structure of the third display module shown in FIG. 4, with the difference being that the display module 100 further includes a third light-shielding layer 6, and the third light-shielding layer 6 is disposed on the side surface of the stress buffer layer 2 close to the second curved portion 122.

Specifically, the third light-shielding layer 6 covers the side surfaces of the base material layer 22 and the first transparent adhesive layer 21 close to the second curved portion 122, so that the third light-shielding layer 6 may shield an area between the second light-shielding layer 5 and the first light-shielding layer 4, which avoids the problem of light leakage at the boundary between the first curved portion 121 and the second curved portion 122 at the large viewing angle.

In an embodiment, a thickness of the third light-shielding layer 6 is the same as the thickness of the first light-shielding layer 4, and a material of the third light-shielding layer 6 is the same as the material of the first light-shielding layer 4, thereby ensuring that the transmittance of the third light-shielding layer 6 is consistent with the transmittance of the first light-shielding layer 4.

In some embodiments, as shown in FIG. 4, the display module 100 further includes a polarizing layer 7 and a second transparent adhesive layer 8. The polarizing layer 7 is disposed between the display panel 3 and the stress buffer layer 2, and the second transparent adhesive layer 8 is disposed between the polarizing layer 7 and the stress buffer layer 2. A material of the second transparent adhesive layer 8 may be, but is not limited to, an optical adhesive. The first light-shielding layer 4 is disposed between the second transparent adhesive layer 8 and the stress buffer layer 2.

In some embodiments, the display module 100 further includes a support layer 9. The support layer 9 is disposed on the surface of the display panel 3 away from the protective layer 1, and a shape of the support layer 9 matches the shape of the display panel 3.

In an embodiment, the support layer 9 is a composite support layer, and the support layer 9 includes, but is not limited to, a back plate 91, an adhesive layer 92, a buffer layer 93, a support substrate 94 and a heat dissipation layer 95. A material of the buffer layer 93 may be, but is not limited to, foam; a material of the support substrate 94 may be, but is not limited to, polyimide; and a material of the heat dissipation layer 95 may be metal.

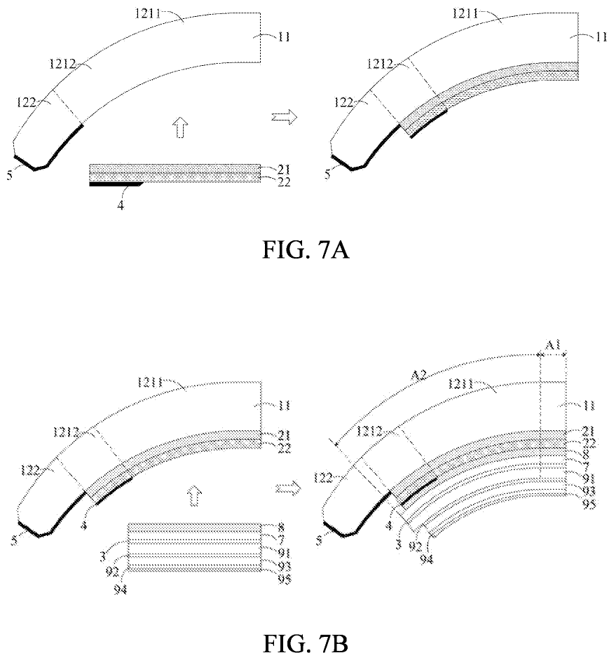

Embodiments of the present application also provides a method of manufacturing a display module, which is used to manufacture the display module according to any one of the above embodiments. FIGS. 7A and 7B schematically illustrate a process of manufacturing the display module according to one or more embodiments of the present application. Considering an example of the third display module shown in FIG. 4, the assembly process of the display module is as follows.

In a first step, a first light-shielding layer 4 is formed in a stress buffer layer 2 or on a surface of the stress buffer layer 2, and an edge of the first light-shielding layer 4 is aligned with an edge of the stress buffer layer 2.

In a second step, a protective layer 1 is provided, and the protective layer 1 includes a planar portion 11 and a curved portion 12 disposed at an edge of the planar portion 11.

In a third step, a surface of a part of the stress buffer layer 2 that is not provided with the first light-shielding layer 4 is bonded to a surface of the planar portion 11 and a surface of a part of the curved portion 12.

In a fourth step, a display panel 3 is bonded to a surface of the stress buffer layer 2 away from the protective layer 1 to form the display module; the display panel 3 includes a planar area A1 and a curved surface area A2 disposed at an edge of the planar area A1. The planar area A1 is disposed opposite to the planar portion 11, and the curved surface area A2 is disposed opposite to the curved portion 12.

As shown in FIG. 7A, in the first step, the first light-shielding layer 4 is formed on the surface of the stress buffer layer 2. Specifically, the stress buffer layer 2 includes a first transparent adhesive layer 21 and a base material layer 22, and the first light-shielding layer 4 is formed on a surface of the base material layer 22 away from the first transparent adhesive layer 21. In the second step, the surface of the first transparent adhesive layer 21 away from the base material layer 22 is bonded to a surface of the protective layer 1. After the bonding process, the shape of the stress buffer layer 2 matches the shape of the protective layer 1.

In some other embodiments, the first light-shielding layer 4 may be formed in the stress buffer layer 2. That is, the first light-shielding layer 4 is formed between the base material layer 22 and the first transparent adhesive layer 21.

In an embodiment, the curved portion 12 includes a first curved portion 121 and a second curved portion 122 connected to the first curved portion 121, and the second curved portion 122 is disposed at a side of the first curved portion 121 away from the planar portion 11. The method of manufacturing the display module further includes the following step.

Before the first light-shielding layer 4 is formed, a second light-shielding layer 5 is formed on a first surface of the second curved portion 122 at a concave side of the second curved portion 122, or a second light-shielding layer 5 is formed on both the first surface and a side surface of the second curved portion 122 away from the first curved portion 121.

In an embodiment, as shown in FIG. 7A, the second curved portion 122 is curved. A surface of the second curved portion 122 protrudes outward, and another opposite surface is concave inward. The second light-shielding layer 5 is formed on the first surface of the second curved portion 122 at the concave side of the second curved portion 122 and the side surface of the second curved portion 122 away from the first curved portion 121.

In an embodiment, as shown in FIG. 7A, the second light-shielding layer 5 is only formed on the surface of the first curved portion 121 close to the display panel 3 in the fourth step. The second light-shielding layer 5 is used to shield the second curved portion 122 to prevent the light emitted by the display panel 3 from exiting from the second curved portion 122.

Since the second light-shielding layer 5 and the first light-shielding layer 4 are designed in segments, the second light-shielding layer 5 is directly disposed on the surface of the second curved portion 122 of the protective layer 1 close to the display panel 3, and the first light-shielding layer 4 is disposed between the stress buffer layer 2 and the display panel 3. In this way, the stress buffer layer 2 may be fully bonded to the inner surface of the protective layer 1 while ensuring that light leakage does not happen to the curved surface area A2 of the display module. Thus, it avoids a step difference existing between a part of the stress buffer layer 2 corresponding to the planar portion 11 and a part of the stress buffer layer 2 corresponding to the curved portion 12. Therefore, it may further ameliorate the uneven stress on the display panel during the process of bonding the curved surface, thereby further reducing the risk of wrinkles or bubbles happening to the display panel.

In an embodiment, the second light-shielding layer 5 is not only formed on the surface of the first curved portion 121 close to the display panel 3, but also formed on the side surface of the second curved portion 122 away from the first curved portion 121, which may avoid the problem of light leakage happening to the side of the protective layer 1 at the large viewing angle.

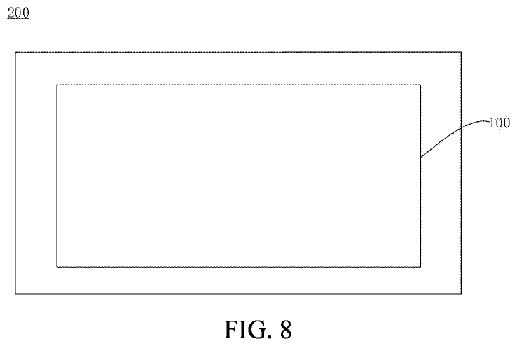

According to the display module provided in the above embodiments of the present application, embodiments of the present application also provide a display apparatus. As shown in FIG. 8, the display apparatus 200 includes the display module 100 provided in any one of the above embodiments. The display apparatus is not limited to a smart phone, a smart watch, a desktop computer, a laptop and a television, etc.

Embodiments of the present application have following beneficial effects. The display module, the method of manufacturing the display module, and the display apparatus are provided in the embodiments of the present application. The display module includes the protective layer, the stress buffer layer, the display panel and the first light-shielding layer. Since the stress buffer layer is added between the protective layer and the display panel, the stress buffer layer may absorb the stress generated during the process of bonding the curved surface, thereby ameliorating the uneven stress on the display panel during the process of bonding the curved surface. Based on this, by arranging the first light-shielding layer in the stress buffer layer or between the stress buffer layer and the display panel, the stress buffer layer may be fully bonded to the inner surface of the protective layer, which avoids the step difference existing between the part of the stress buffer layer corresponding to the planar portion and the part of the stress buffer layer corresponding to the curved portion. Therefore, it may further ameliorate the uneven stress on the display panel during the process of bonding the curved surface, thereby further reducing the risk of wrinkles or bubbles happening to the display panel.

Some embodiments of the present application have been described in detail above. The embodiments are described for illustrative purposes only and are not intended to limit the present application. Many modifications or equivalent substitutions with respect to the embodiments may occur to those of ordinary skill in the art based on the present application and thus shall fall within the scope of the present application defined by the appended claims.

What is claimed is:

1. A display module, comprising:
a display panel comprising a planar area and a curved surface area disposed at an edge of the planar area;
a stress buffer layer disposed on a light exit side of the display panel to be opposite to the planar area and a part of the curved surface area;
a protective layer disposed on a surface of the stress buffer layer away from the display panel, wherein the protective layer comprises a planar portion and a curved portion, the planar portion is disposed opposite to the planar area, and the curved portion is disposed opposite to the curved surface area; and
a first light-shielding layer disposed in the stress buffer layer or between the stress buffer layer and the display panel to be opposite to a part of the curved portion, wherein an edge of the first light-shielding layer is aligned with an edge of the stress buffer layer.

2. The display module according to claim 1, wherein the curved portion comprises a first curved portion, and a second curved portion connected to the first curved portion and disposed on a side of the first curved portion away from the planar portion;
the first light-shielding layer is disposed opposite to at least a part of the first curved portion; and
the display module further comprises a second light-shielding layer at least partially disposed on a surface of the second curved portion close to the display panel.

3. The display module according to claim 2, wherein an edge of the first light-shielding layer close to the second curved portion is aligned with an edge of the second light-shielding layer close to the first curved portion.

4. The display module according to claim 2, wherein an end of the first light-shielding layer close to the second curved portion overlaps an end of the second light-shielding layer close to the first curved portion.

5. The display module according to claim 2, wherein the second light-shielding layer is partially disposed on a side surface of the second curved portion away from the first curved portion.

6. The display module according to claim 2, wherein the second light-shielding layer has a thickness equal to that of the first light-shielding layer, and comprises a same material as the first light-shielding layer.

7. The display module according to claim 2, wherein the first curved portion has a greater radius of curvature than the second curved portion.

8. The display module according to claim 1, wherein the first light-shielding layer has a thickness greater than or equal to 15 microns and less than or equal to 20 microns.

9. The display module according to claim 2, wherein an end of the display panel close to the second curved portion protrudes from each of an end of the stress buffer layer close to the second curved portion and an end of the first light-shielding layer close to the second curved portion.

10. The display module according to claim 2, further comprising a third light-shielding layer disposed on a side surface of the stress buffer layer close to the second curved portion.

11. The display module according to claim 1, wherein the stress buffer layer comprises:
a first transparent adhesive layer disposed on an inner surface of the planar portion and an inner surface of a part of the curved portion; and
a base material layer disposed between the first transparent adhesive layer and the display panel;
wherein the first light-shielding layer is disposed between the base material layer and the display panel or between the first transparent adhesive layer and the base material layer.

12. The display module according to claim 11, wherein the base material layer has an elastic modulus greater than or equal to 2 GPa and less than or equal to 6 GPa.

13. The display module according to claim 11, wherein the base material layer comprises polyethylene terephthalate or polyimide.

14. The display module according to claim 11, wherein the base material layer has a thickness greater than or equal to 50 microns and less than or equal to 100 microns.

15. The display module according to claim 11, wherein the first transparent adhesive layer has a thickness greater than or equal to 50 microns and less than or equal to 200 microns.

16. The display module according to claim 1, further comprising:
a polarizing layer disposed between the display panel and the stress buffer layer; and
a second transparent adhesive layer disposed between the polarizing layer and the stress buffer layer,
wherein the first light-shielding layer is disposed between the second transparent adhesive layer and the stress buffer layer.

17. The display module according to claim 1, further comprising a support layer disposed on a surface of the display panel away from the protective layer.

18. A method of manufacturing a display module, comprising:
forming a first light-shielding layer in a stress buffer layer or on a surface of the stress buffer layer, an edge of the first light-shielding layer being aligned with an edge of the stress buffer layer;
providing a protective layer comprising a planar portion and a curved portion disposed at an edge of the planar portion;
bonding a surface of a part of the stress buffer layer that is not provided with the first light-shielding layer to a surface of the planar portion and a surface of a part of the curved portion; and
bonding a display panel to a surface of the stress buffer layer away from the protective layer to form the display module, wherein the display panel comprises a planar area and a curved surface area disposed at an edge of the planar area, the planar area is disposed opposite to the planar portion, and the curved surface area is disposed opposite to the curved portion.

19. The method according to claim 18, wherein the curved portion comprises a first curved portion, and a second curved portion connected to the first curved portion and disposed on a side of the first curved portion away from the planar portion,
the method further comprising: before forming the first light-shielding layer, forming a second light-shielding layer on a first surface of the second curved portion at a concave side of the second curved portion or on both the first surface and a side surface of the second curved portion away from the first curved portion.

20. A display apparatus, comprising a display module,
wherein the display module comprises:
a display panel comprising a planar area and a curved surface area disposed at an edge of the planar area;
a stress buffer layer disposed on a light exit side of the display panel to be opposite to the planar area and a part of the curved surface area;
a protective layer disposed on a surface of the stress buffer layer away from the display panel, wherein the protective layer comprises a planar portion and a curved portion, the planar portion is disposed opposite to the planar area, and the curved portion is disposed opposite to the curved surface area; and
a first light-shielding layer disposed in the stress buffer layer or between the stress buffer layer and the display panel to be opposite to a part of the curved portion, wherein an edge of the first light-shielding layer is aligned with an edge of the stress buffer layer.
